(19) United States
(12) Patent Application Publication
(10) Pub. No.: US 2005/0074914 A1
(43) Pub. Date: Apr. 7, 2005

(54) Semiconductor device and method of fabrication the same

(75) Inventors: Shih-Chang Chang, Hsinchu (TW); Chun-Hsiang Fang, Yilan Hsien (TW); Yaw-Ming Tsai, Taichung Hsien (TW)

Correspondence Address: LIU & LIU, 811 WEST 7TH STREET, SUITE 1100, LOS ANGELES, CA, 90017, US

(73) Assignee: Toppoly Optoelectronics Corp.

(21) Appl. No.: 10/960,183

(22) Filed: Oct. 6, 2004

Related U.S. Application Data
(63) Continuation-in-part of application No. 10/833,487, filed on Apr. 27, 2004.

(30) Foreign Application Priority Data
Oct. 6, 2003 (TW) 92127643

(51) Int. Cl. H01L 21/00

(52) U.S. Cl. 438/48

(57) ABSTRACT

A method of forming a semiconductor device. A first and a second semiconductor structures are formed. A semiconductor layer is provided. A first masking layer over a first region of the semiconductor layer is provided. The first masking layer comprises a material that provides a permeable barrier to dopant. The semiconductor layer, including the first region covered by the first masking layer, is exposed to a first dopant. The first region covered by the first masking layer is lightly doped with the first dopant in comparison to a second region not covered by the first masking layer.

### RELATED APPLICATION

This application is a continuation-in-part of U.S. patent application Ser. No. 10/833,487, filed Apr. 27, 2004, Self-Aligned LDD Thin-Film Transistor and Method of Fabricating the Same, which is incorporated by reference herein, as if fully set forth herein.

### BACKGROUND OF THE INVENTION

1. Field of the Invention

The invention relates to a thin film transistor (TFT) device, and more particularly to a lightly doped drain (LDD) structure for a TFT device. Two LDD structures are provided for two TFT devices working at different driving voltages, and a LDD structure with two lateral lengths is provided for a TFT device.

2. Description of the Related Art

Active matrix liquid crystal displays (LCDs) typically employs thin film transistors (TFTs) as pixel switching elements. TFTs are classified as amorphous silicon (a-Si) TFTs and polysilicon TFTs according to the materials used for an active layer. Compared with a-Si TFTs, polysilicon TFTs have the advantages of high carrier mobility, high driving-circuit integration and low leakage current, and are often applied to high-speed operation applications, such as static random access memory (SPAM). One of the major drawbacks of these TFTs is OFF-state leakage current, which causes charge loss in LCDs and high standby power dissipation in SRAMs. Seeking to address this issue, conventional lightly doped drain (LDD) structures have been used to reduce the drain junction field, thereby reducing the leakage current. In current semiconductor integrated circuit methods, lithography is employed to define the location and size of the LDD structure. Process tolerance of photo misalignment and critical length deviation, however, become more restricted as TFT size is continuously reduced.

In conventional LDD processing, a photoresist layer is used as a mask for a heavily-doped ion implantation to form a heavily-doped region in a polysilicon layer. A gate electrode is then formed on the polysilicon layer and used as a mask for a lightly-doped ion implantation to form a lightly-doped region on the exposed area of the polysilicon layer. Thus, the heavily-doped region serves as a source/drain region, the lightly-doped region serves as an LDD structure, and the undoped area of the polysilicon layer serves as a channel region. The pattern of the gate electrode, however, must be accurately controlled to ensure proper placement. The exposure technique is additionally limited by potential photo misalignment, which results in shifting of the gate electrode and the LDD structure. Moreover, because the ion implantation process is performed twice, the LDD structure is subjected to further shifting. Additionally, the procedure of the conventional method is complex, has a low production yield rate, lacks accurate control over the lateral length of the LDD structure, and cannot fabricate two LDD structures with different lateral lengths for different driving-voltage devices simultaneously. Thus, scale reducibility and device operating speed are not reliable.

### SUMMARY OF THE INVENTION

Accordingly, the present invention provides two self-aligned LDD structures for two TFT devices working at different driving voltages.

The present invention provides a self-aligned LDD structure with two lateral lengths for a TFT device.

According to embodiments of the present invention, a method of forming a semiconductor device comprises forming a first and a second semiconductor structures. Each semiconductor structure comprises providing a semiconductor layer, providing a first masking layer over a first region of the semiconductor layer, said first masking layer comprising a material that provides a permeable barrier to dopant, and exposing the semiconductor layer, including the first region covered by the first masking layer, to a first dopant, wherein the first region covered by the first masking layer is lightly doped with the first dopant in comparison to a second region not covered by the first masking layer, wherein the first region of the first semiconductor structure is of a different lateral length that the first region of the second semiconductor structure.

According to embodiments of the present invention, a method of forming a semiconductor device comprises providing a semiconductor layer, providing a first masking layer over a first region of the semiconductor layer, said first masking layer comprising a material that provides a permeable barrier to dopant, exposing the semiconductor layer, including the first region covered by the first masking layer, to a first dopant, wherein the first region covered by the first masking layer is lightly doped with the first dopant in comparison to a second region not covered by the first masking layer, and providing a second masking layer over the second region of the semiconductor layer, said second masking layer comprising a material that provides a permeable barrier to dopant, wherein the second masking layer is thinner than the first masking layer.

According to embodiments of the present invention, a method of forming a semiconductor device comprises providing a semiconductor layer, providing a first masking layer over a first region of the semiconductor layer, said first masking layer comprising a material that provides a permeable barrier to dopant, and exposing the semiconductor layer, including the first region covered by the first masking layer, to a first dopant, wherein the first region covered by the first masking layer is lightly doped with the first dopant in comparison to a second region not covered by the first masking layer, wherein the first region comprises first and second sections, wherein the first section is of a different lateral length that the second section.

### DESCRIPTION OF THE DRAWINGS

The present invention will become more fully understood from the detailed description given hereinbelow and the accompanying drawings, given by way of illustration only and thus not intended to be limitative of the present invention.

FIG. 1 is a cross-section of two self-aligned LDD structures according to the first embodiment of the present invention.

FIGS. 2A to 2G are cross-sections of a fabrication method for the self-aligned LDD structures shown in FIG. 1.

FIG. 3 is a cross-section of two self-aligned LDD structures according to the second embodiment of the present invention.

FIG. 4 is a cross-section of self-aligned LDD structures according to the third embodiment of the present invention.

FIG. 5 is a cross-section of a self-aligned LDD structure according to the fourth embodiment of the present invention.

FIGS. 6A-6C are schematic diagrams of a fabrication method for the self-aligned LDD structure shown in FIG. 5.

FIG. 7 is a cross-section of a self-aligned LDD structure according to the fifth embodiment of the present invention.

FIG. 8 is a cross-section of a self-aligned LDD structure according to the sixth embodiment of the present invention.

FIG. 9 is a cross-section of a self-aligned LDD structure according to the seventh embodiment of the present invention.

FIGS. 10A-10C are schematic diagrams of a fabrication method for the self-aligned LDD structure shown in FIG. 9.

FIG. 11 is a cross-section of a self-aligned LDD structure according to the eighth embodiment of the present invention.

FIG. 12 is a cross-section of a self-aligned LDD structure according to the ninth embodiment of the present invention.

FIGS. 13A to 13E are cross-sections of a photolithography process with an attenuated phase shifting mask for a self-aligned LDD structure according to the tenth embodiment of the present invention.

FIG. 14 is a schematic diagram of a display device comprising the self-aligned LDD structures in accordance with embodiments of the present invention.

FIG. 15 is a schematic diagram of an electronic device comprising the display device in accordance with embodiments of the present invention.

### DETAILED DESCRIPTION OF THE INVENTION

### FIRST EMBODIMENT

The present invention provides two LDD structures for two TFT devices working at different driving voltages. Particularly, a gate insulating layer formed underneath a gate electrode layer has two shielding regions exposed laterally adjacent to the gate electrode layer. The shielding regions are used as a mask for performing an ion implantation process, thus obtaining a self-aligned LDD structure and a source/drain diffusion region simultaneously. The TFT devices are used in N-MOS TFT applications or P-MOS TFT applications. The TFT devices are used in a pixel array area, a peripheral driving-circuit area or a combination thereof.

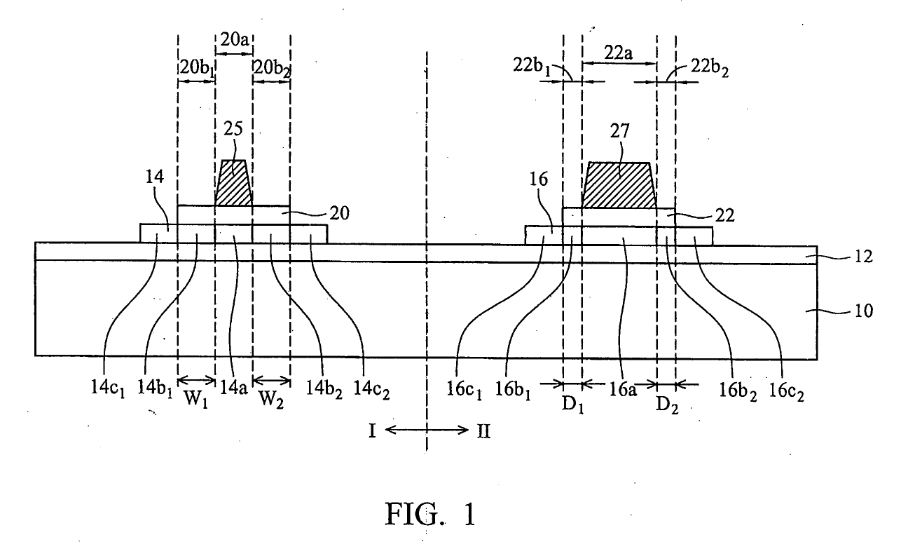

FIG. 1 is a cross-section of two self-aligned LDD structures according to the first embodiment of the present invention. A substrate 10 comprises a first TFT area I and a second TFT area II, and a buffer layer 12 is deposited on the substrate 10. In the first TFT area I, a first active layer 14, a first gate insulating layer 20 and a first gate electrode layer 25 are formed on the buffer layer 12 successively. In the second TFT area II, a second active layer 16, a second gate insulating layer 22 and a second gate electrode layer 27 are formed on the buffer layer 12 successively.

The substrate 10 is a transparent insulating substrate, such as a glass substrate. Either the first TFT area I or the second TFT area II is a peripheral driving-circuit area or a pixel array area. The buffer layer 12 is a dielectric layer, such as a silicon oxide layer, for improving the formation of the active layers 14 and 16 overlying the substrate 10. Each first active layer 14 and second active layer 16 is a semiconductor silicon layer, such as a polysilicon layer. Each first gate insulating layer 20 and second gate insulating layer 22 may be a silicon oxide layer, a silicon nitride layer, a SiON layer or a combination thereof. Each first gate electrode layer 25 and second gate electrode layer 27 may be a metallic layer or a polysilicon layer.

The structural characteristics of the first TFT area I are described in the following. The first active layer 14 comprises an undoped region 14a, two lightly-doped regions 14b₁ and 14b₂, and two heavily-doped regions 14c₁ and 14c₂. The undoped region 14a serves as a channel region. The first lightly-doped region 14b₁ and the second lightly-doped region 14b₂ extend laterally away from the undoped region 14a, respectively, to serve as an LDD structure. The first heavily-doped region 14c₁ and the second heavily-doped region 14c₂ extend laterally away from the two lightly-doped regions 14b₁ and 14b₂, respectively, to serve as a source/drain diffusion region. The LDD structure has a doping concentration less than 2×10¹⁸ atom/cm³, and the source/drain diffusion region has a doping concentration of 2×10¹⁹˜2×10²¹ atom/cm³.

The first gate insulating layer 20 comprises a central region 20a and two shielding regions 20b, and 20b₂. The central region 20a covers the undoped region 14a and is covered by the bottom of the first gate electrode layer 25. The two shielding regions 20b₁ and 20b₂ extend laterally away from the central region 20a, respectively, without being covered by the first gate electrode layer 25. The first shielding region 20b₁ also covers the first lightly-doped region 14b₁, and the second shielding region 20b₂ covers the second lightly-doped region 14b₂. Thus, using the shielding regions 20b₁ and 20b₂ as an ion-implantation mask, the LDD structure and the source/drain diffusion region can be achieved simultaneously with only one ion implantation process of adequate doping energy and dosage.

The first shielding region 20b₁ has a lateral length W₁ corresponding to a lateral length of the first lightly-doped region 14b₁, and the second shielding region 20b₂ has a lateral length W₂ corresponding to a lateral length of the second lightly-doped region 14b₂. Preferably, W₁=0.1 μm˜2.0 μm, and W₂=0.1 μm˜2.0 μm. Depending on requirements for circuit designs, the size and symmetry of the lateral lengths W₁ and W₂ may be adequately modified, for example Wₗ=W₂.

The structural characteristics of the second TFT area II are described in the following. The second active layer 16 comprises an undoped region 16a, two lightly-doped regions 16b₁ and 16b₂, and two heavily-doped regions 16c₁ and 16c₂. The undoped region 16a serves as a channel region. The first lightly-doped region 16b₁ and the second lightly-doped region 16b₂ extend laterally away from the undoped region 16a, respectively, to serve as an LDD structure. The first heavily-doped region 16c₁ and the second heavily-doped region 16c₂ extend laterally away from the two lightly-doped regions 16b₁ and 16b₂, respectively, to serve as a source/drain diffusion region. The LDD structure has a doping concentration less than 2×10¹⁸ atom/cm³, and the source/drain diffusion region has a doping concentration of 2×10¹⁹˜2×10²¹ atom/cm³.

The second gate insulating layer 22 comprises a central region 22a and two shielding regions 22b₁ and 22b₂. The central region 22a covers the undoped region 16a and is covered by the bottom of the second gate electrode layer 27. The first shielding region 22b₁ and the second shielding region 22b₂ extend laterally away from the central region 22a, respectively, without being covered by the second gate electrode layer 27. Also, the first shielding region 22b₁ covers the first lightly-doped region 16b₁, and the second shielding region 22b₂ covers the second lightly-doped region 16b₂. Thus, using the two shielding regions 22b₁ and 22b₂ as an ion-implantation mask, the LDD structure and the source/drain diffusion region can be achieved simultaneously with only one ion implantation process of adequate doping energy and dosage.

The first shielding region 22b₁ has a lateral length D₁ corresponding to a lateral length of the first lightly-doped region 16b₁, and the second shielding region 22b₂ has a lateral length D₂ corresponding to a lateral length of the second lightly-doped region 16b₂. Preferably, D₁=0.1 μm˜2.0 μm, and D₂=0.1 μm˜2.0 μm. Depending on requirements for circuit designs, the size and symmetry of the lateral lengths D₁ and D₂ may be adequately modified, for example D₁=D₂. In addition, according to requirements for reliability and current designs, the relationship between W₁, W₂, D₁ and D₂ may be adequately modified. For example, W₁ (or W₂) is not equal to D₁ (or D₂). Preferably, when the first TFT area I is a pixel array area and the second TFT area II is a peripheral driving-circuit area, W₁, W₂, D₁ and D₂ satisfy the formula: W₁ (or W₂)>D₁(or D₂).

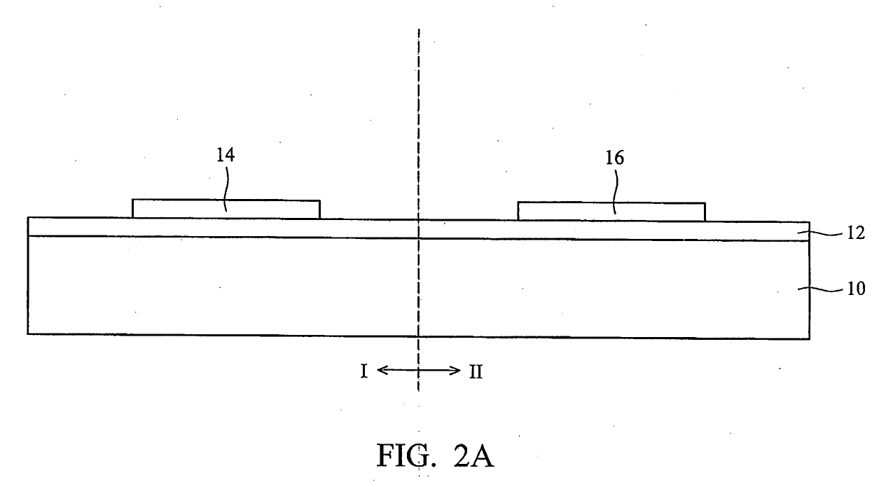

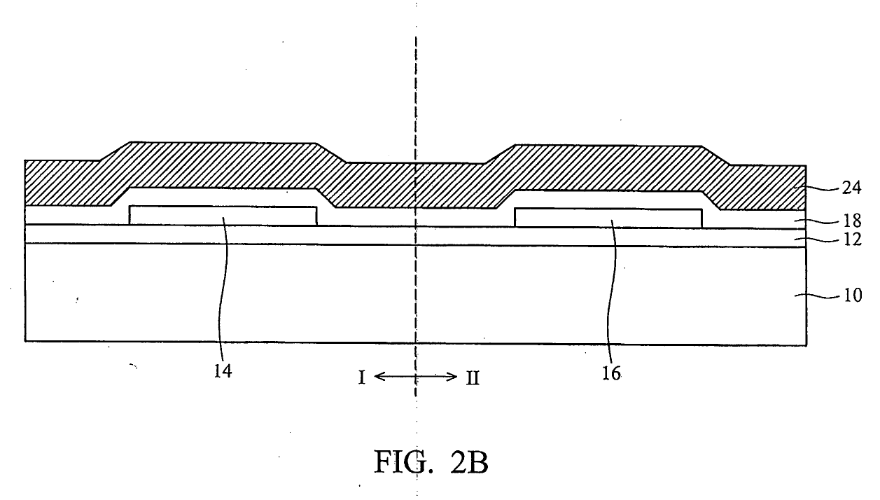

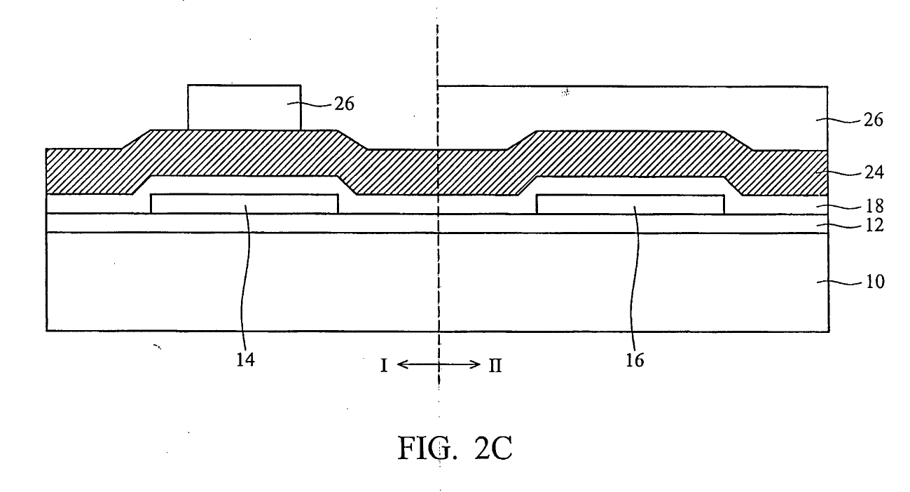

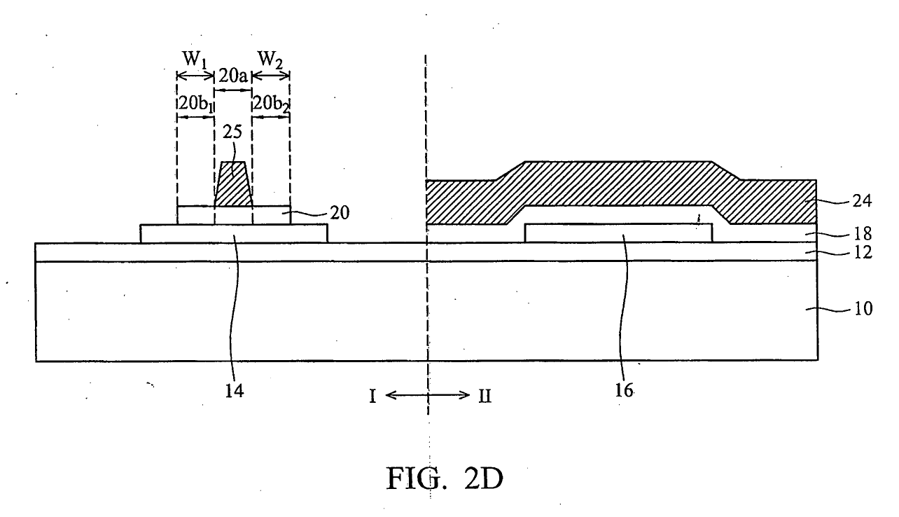

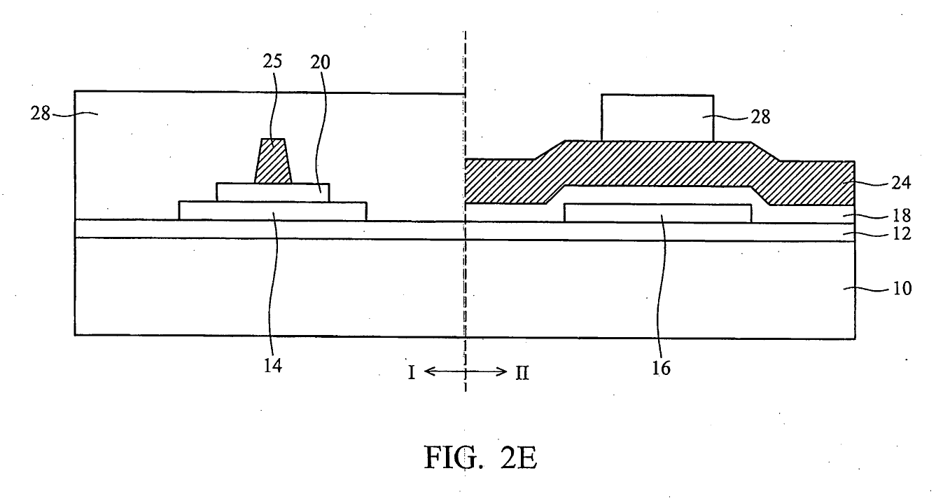

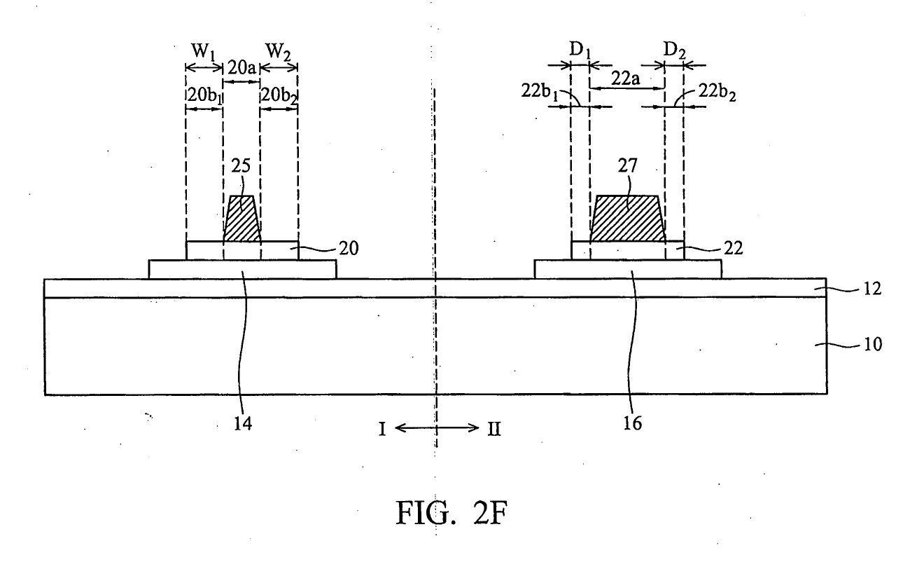

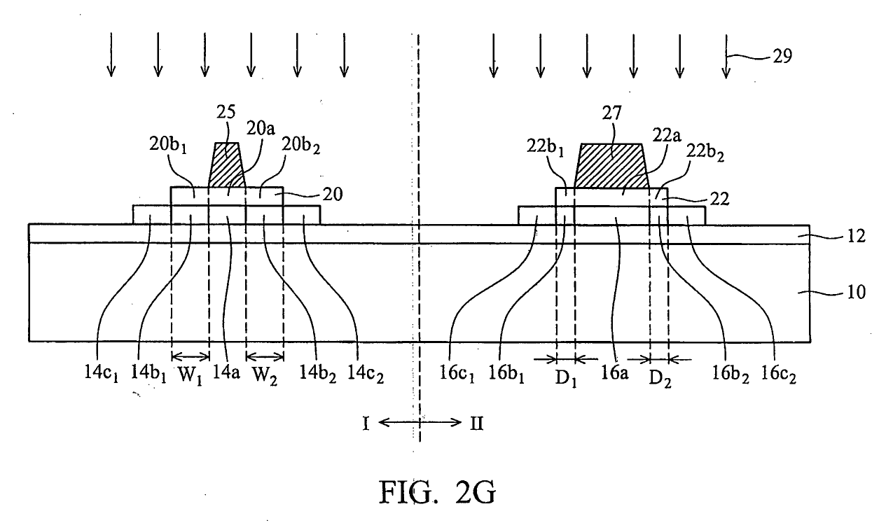

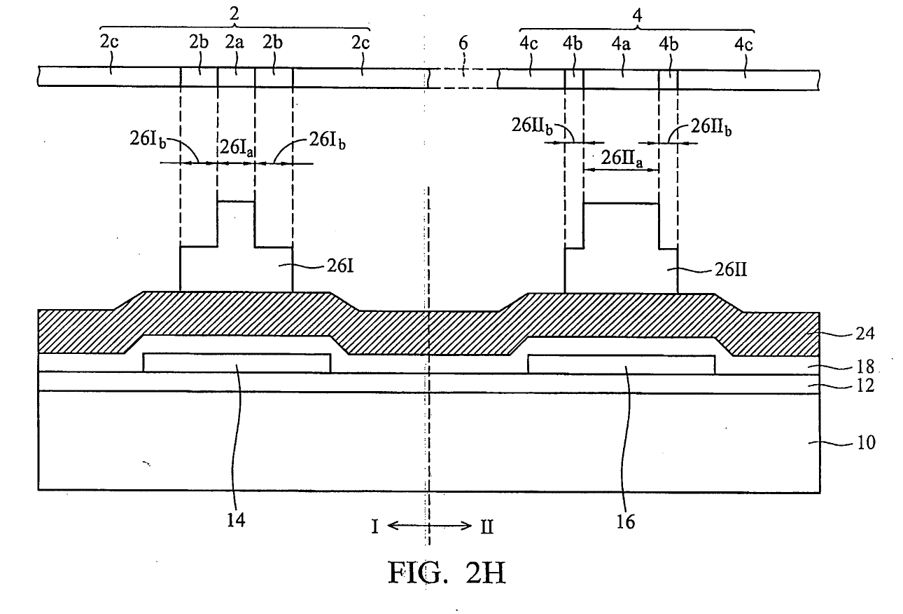

The fabrication method for the self-aligned LDD structure is described in the following. FIGS. 2A to 2G are cross-sections of a fabrication method for the self-aligned LDD structures shown in FIG. 1.

In FIG. 2A, the substrate 10 comprises a first TFT area I and a second TFT area II, and a buffer layer 12 is deposited on the substrate 10. Then, a first active layer 14 and a second active layer 16 are formed on the buffer layer 12 of the first TFT area I and the second TFT area II, respectively. The thickness and fabrication method of the active layers 14 and 16 are not limited. For example, low temperature polycrystalline silicon (LTPS) process is employed to form an amorphous silicon layer on a glass substrate, and then heat treatment or excimer laser annealing (ELA) is used to transform the amorphous silicon layer into a polysilicon layer.

In FIG. 2B, an insulating layer 18 and a conductive layer 24 are successively deposited on the active layers 14 and 16 and the buffer layer 12. The insulating layer 18 may be a silicon oxide layer, a silicon nitride layer, a SiON layer or a combination thereof. The conductive layer 24 may be a metallic layer or a polysilicon layer.

In FIG. 2C, a first patterned photoresist layer 26 is formed on the conductive layer 24 to cover a predetermined gate pattern of the first TFT area I, and cover the entire second TFT area II. Then, in FIG. 2D, the first patterned photoresist layer 26 is used as a mask and an etching process is performed to remove the exposed regions of the conductive layer 24 and the insulating layer 18. Thus, in the first TFT area I, the conductive layer 24 is patterned as a first gate electrode layer 25, and the insulating layer 18 is patterned as a first gate insulating layer 20. Next, the first patterned photoresist layer 26 is removed. Preferably, the first gate electrode layer 25 has a trapezoid profile with an upper base shorter than a lower base, thus the first gate insulating layer 20 covered by the bottom of the first gate electrode layer 25 serves as a central region 20a. The first gate insulating layer 20 exposed laterally adjacent to the first gate electrode layer 25 also becomes two shielding regions 20b₁ and 20b₂. Moreover, the first gate insulating layer 20 exposes a predetermined source/drain diffusion region of the first active layer 14. Preferably, the first shielding region 20b₁ , has a lateral length W₁ of 0.1 μm˜2.0 μm, and the second shielding region 20b₂ has a lateral length W₂ of 0.1 μm˜2.0 μm. Depending on requirements for circuit designs, the size and symmetry of the lateral lengths W₁ and W₂ may be adequately modified, for example W₁=W₂.

An effective etching method employed to obtain the patterned structures in FIG. 2D may be plasma etching or reactive ion etching. Preferably, the etching method uses a reactive gas mixture of an oxygen-containing gas and a chlorine-containing gas, and adjusts the individual flow of the oxygen-containing gas or the chlorine-containing gas in a timely manner. For example, during the etching process for the first gate electrode layer 25, the flow of the chlorine-containing gas is gradually tuned to reach a maximum, even if chlorine-containing gas is the only gas used, resulting in a rectangular profile of the first gate electrode layer 25. During the etching process for the first gate insulating layer 20, the flow of the oxygen-containing gas is gradually increased to reach a maximum, thus a part of the first patterned photoresist layer 26 is removed and the first gate electrode layer 25 exposed again by the first photoresist layer 25 is etched simultaneously. This results in a trapezoid profile of the first gate electrode layer 25, and completes the two shielding regions 20b, and 20b₂.

In FIG. 2E, a second patterned photoresist layer 28 is formed to cover the entire first TFT area I, and cover a predetermined gate pattern of the second TFT area II. Then, in FIG. 2F, the second patterned photoresist layer 28 is used as a mask and an etching process is performed to remove the exposed regions of the conductive layer 24 and the insulating layer 18. Thus, in the second TFT area II, the conductive layer 24 is patterned as a second gate electrode layer 27, and the insulating layer 18 is patterned as a second gate insulating layer 22. Next, the second patterned photoresist layer 28 is removed. Preferably, the second gate electrode layer 27 has a trapezoid profile with an upper base shorter than a lower base, thus the second gate insulating layer 22 covered by the bottom of the second gate electrode layer 27 serves as a central region 22a. The second gate insulating layer 22 exposed laterally adjacent to the second gate electrode layer 27 also becomes two shielding regions 22b₁ and 22b₂. Moreover, the second gate insulating layer 22 exposes a predetermined source/drain diffusion region of the second active layer 16. Preferably, the first shielding region 22b₁ has a lateral length D₁ of 0.1 μm˜2.0 μm, and the second shielding region 22b₂ has a lateral length D₂ of 0.1 μm˜2.0 μm. Depending on requirements for circuit designs, the size and symmetry of the lateral lengths D₁ and D₂ may be adequately modified, for example D₁=D₂. In addition, according to requirements for reliability and current designs, the relationship between W₁, W₂, D₁ and D₂ may be adequately modified. For example, W₁ (or W₂) is not equal to D₁ (or D₂). Preferably, a lateral length of an LDD structure for a pixel array area is greater than a lateral length of an LDD structure for a peripheral driving-circuit area. An effective etching method, such as plasma etching or reactive ion etching, employed to obtain the patterned structures in FIG. 2F is substantially similar to that described in FIG. 2D, with the similar portions omitted herein.

Finally, in FIG. 2G, the first gate electrode layer 25, and the shielding regions 20b₁ and 20b₂ are used as a mask, and an ion implantation process 29 is performed to form an undoped region 14a, two lightly-doped regions 14b, and 14b₂, and two heavily-doped regions 14c₁ and 14c₂ in the first active layer 14. The two lightly-doped regions 14b₁ and 14b₂ underlying the two shielding regions 20b₁ and 20b₂ serve as an LDD structure. The two heavily-doped regions 14c₁ and 14c₂ exposed laterally adjacent to the first gate electrode layer 25 serve as a source/drain diffusion region. The undoped region 14a underlying the central region 20a serves as a channel region. Since the two shielding regions 20b₁ and 20b₂ are used as an ion-implantation mask for the LDD structure, a lateral length of the first lightly-doped region 14b₁ corresponds to the lateral length W₁ of the first shielding region 20b₁ and a lateral length of the second lightly-doped region 14b₂ corresponds to the lateral length W₂ of the second shielding region 20b₂.

Simultaneously when the ion implantation process 29 is performed, the second gate electrode layer 27 and the shielding regions 22b₁ and 22b₂ are used as a mask, two lightly-doped regions 16b₁ and 16b₂, and two heavily-doped regions 16c₁ and 16c₂ are formed in the second active layer 16. The two lightly-doped regions 16b₁ and 16b₂ underlying the two shielding regions 22b, and 22b₂ serve as an LDD structure. The two heavily-doped regions 16c₁ and 16c₂ exposed laterally adjacent to the second gate electrode layer 27 serve as a source/drain diffusion region. The undoped region 16a underlying the central region 22a serves as a channel region. Since the two shielding regions 22b₁ and 22b₂ are used as an ion-implantation mask for the LDD structure, a lateral length of the first lightly-doped region 16b₁ corresponds to the lateral length D₁ of the first shielding region 22b₁, and a lateral length of the second lightly-doped region 16b₂ corresponds to the lateral length D₂ of the second shielding region 22b₂.

For the first TFT area I, the lateral length W₁ or W₂ of the shielding region 20b₁ or 20b₂ is 0.1˜2.0 μm, the doping energy is 10˜100 KeV, and a doping concentration of the lightly-doped region 14b₁ or 14b₂ is less than 2×10¹⁸ atom/cm³, and a doping concentration of the heavily-doped region 14c₁ and 14c₂ is 2×10¹⁹˜2×10²¹ atom/cm³. For the second TFT area II, the lateral length D₁ or D₂ of the shielding region 22b₁ or 22b₂ is 0.1˜2.0 μm, the doping energy is 10˜100 KeV, and a doping concentration of the lightly-doped region 16b₁ or 16b₂ is less than 2×10¹⁸ atom/cm³, and a doping concentration of the heavily-doped region 16c₁ and 16c₂ is 2×10¹⁹ ˜2×10²¹ atom/cm³. The thin film transistor is used in an N-MOS TFT, thus the LDD structure is an N⁻-doped region, and the source/drain diffusion region is an N⁺-doped region. Alternatively, the thin film transistor is used in a P-MOS TFT, thus the LDD structure is a P⁻-doped region, and the source/drain diffusion region is a P⁺-doped region. Subsequent interconnect process including formation of inter-dielectric layers, contact vias and interconnects overlying the thin film transistor is omitted herein.

The self-aligned LDD structure and the fabrication method thereof have the following advantages.

First, by adjusting parameters of the etching process, the lateral lengths W₁, W₂, D₁ and D₂ of the shielding regions 20b₁, 20b₂, 22b₁ and 22b₂ can be accurately controlled, thus ensuring proper positioning of the LDD structure and electric performance of the thin film transistor.

Second, since an extra photomask or a spacer structure for defining the LDD structure are omitted, shifting of the LDD structure due to photo misalignment in exposure technique is prevented, further improving accuracy in positioning the LDD structure.

Third, compared with the conventional method, the present invention eliminates one photomask and one step of the ion implantation process, thus simplifying the procedure, decreasing process costs, increasing product yield and production rate. Additionally, the method is highly applicable to mass production.

Fourth, the ion implantation process can be performed simultaneously in the first TFT area I and the second TFT area II to modulate electric characteristics, and the lateral lengths W₁, W₂, D₁ and D₂ of the shielding regions 20b₁, 20b₂, 22b₁ and 22b₂ can modify the lateral lengths of the lightly-doped regions 14b₁, 14b₂, 16b₁ and 16b₂, thus two LDD structures with different lateral lengths can be simultaneously achieved on two TFT areas with different driving voltages. Thus, ensuring reliability and operating speed of two driving-voltage devices simultaneously.

In addition, the above-described steps for patterning the gate electrode layers 25 and 27 and the gate insulating layers 20 and 22 shown in FIGS. 2C-2F may be replaced by one step of photolithography with an attenuated phase shifting mask, in which two protrusion-shaped photoresist layers are used as a mask and an etching method is performed to complete the gate electrode layers 25 and 27 and the gate insulating layers 20 and 22 simultaneously.

FIG. 2H is a cross-section of a step of photolithography with an attenuated phase shifting mask for the gate electrode layers 25 and 27 and the gate insulating layers 20 and 22 shown in FIG. 1. After completing the steps shown in FIGS. 2A and 2B, an attenuated phase shifting mask 6 is provided and a lithography process is performed on a photoresist layer 26 to form a first protrusion-shaped photoresist layer 26I in the first TFT area I and a second protrusion-shaped photoresist layer 26II in the second TFT area II, simultaneously. For example, the attenuated phase shifting mask 6 comprises a first partial exposure area 2 and a second partial exposure area 4. The first partial exposure area 2 is disposed overlying the first TFT area I, and comprises an opaque area 2a of approximately 0% transparency, two phase-shifting areas 2b extending laterally away from the opaque area 2a respectively, and two transparent areas 2c extending laterally away from the two phase-shifting areas 2b respectively. The opaque area 2a corresponds to the first gate electrode layer 25, the two phase-shifting areas 2b correspond to two lightly-doped regions 14b₁ and 14b₂ respectively, and the two transparent areas 2c correspond to two heavily-doped regions 14c₁ and 14c₂ respectively. Generally, the transparency of the phase-shifting area 2b is different from the transparency of the transparent area 2c, and the transparency difference can be adequately modified in accordance with requirements for product and process designs. Similarly, the second partial exposure area 4 is disposed overlying the second TFT area II, and comprises an opaque area 4a of approximately 0% transparency, two phase-shifting areas 4b extending laterally away from the opaque area 4a respectively, and two transparent areas 4c extending laterally away from the two phase-shifting areas 4b respectively. The opaque area 4a corresponds to the second gate electrode layer 27, the two phase-shifting areas 4b correspond to two lightly-doped regions 16b₁ and 16b₂ respectively, and the two transparent areas 4c correspond to two heavily-doped regions 16c₁ and 16c₂ respectively. Generally, the transparency of the phase-shifting area 4b is different from the transparency of the transparent area 4c, and the transparency difference can be adequately modified in accordance with requirements for product and process designs. When the attenuated phase shifting mask 6 is utilized to perform the photolithography process on a positive-type photoresist, the areas 2a˜2c and 4a˜4c having different transparencies make corresponding areas on the photoresist respectively receive different light intensity to achieve an incomplete exposure result. Therefore, each developed depth of the corresponding areas on the photoresist layer 26 is different, and the protrusion-shaped photoresist layers 26I and 26II are formed in the first TFT area I and the second TFT area II, simultaneously. Preferably, the first protrusion-shaped photoresist layer 26I has a first region 26Iₐ thicker than a second region 26I_{b}, and the second protrusion-shaped photoresist layer 26II has a first region 26IIₐ thicker than a second region 26II_{b}. The lateral lengths of the second regions 26I_{b} and 26II_{b} can be modified depending on the lateral lengths of the LDD structures of the TFT areas I and II.

Next, the two protrusion-shaped photoresist layers 26I and 26II are used as a mask and an etching method is employed to remove the exposed regions of the conductive layer 24 and the insulating layer 18. Then, the two protrusion-shaped photoresist layers 26I and 26II are continuously thinned until the second regions 26I_{b} and 26II_{b} and the conductive layer 24 underlying the second regions 26I_{b} and 26II_{b} are completely removed, thus completing the gate electrode layer 25 and 27 and the gate insulating layers 20 and 22 shown in FIG. 2F. The two protrusion-shaped photoresist layers 26I and 26II are then removed.

### SECOND EMBODIMENT

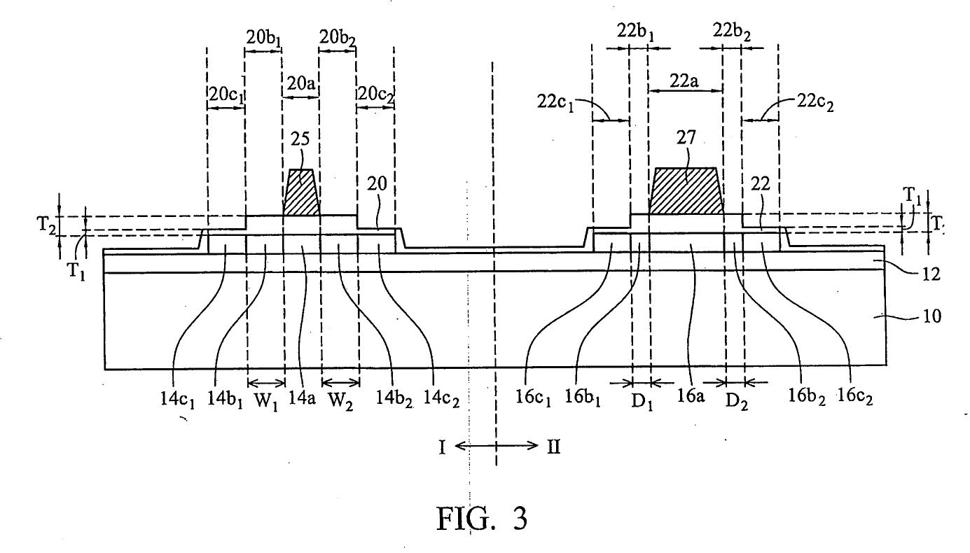

FIG. 3 is a cross-section of two self-aligned LDD structures according to the second embodiment of the present invention. Elements in the second embodiment are substantially similar to those in the first embodiment, with the similar portions omitted herein.

In the first TFT area I, the first gate insulating layer 20 further comprises a first extending region 20c, and a second extending region 20c₂. The first extending region 20c₁ extends laterally away from the first shielding region 20b₁ and covers the first heavily-doped region 14c₁. The second extending region 20c₂ extends laterally away from the second shielding region 20b₂ and covers the second heavily-doped region 14c₂. The first extending region 20c₁ has a thickness T₁ less than a thickness T₂ of the first shielding region 20b₁. Preferably, the thickness T₁ is far less than the thickness T₂. Alternatively, the thickness T₁ is close to a minimum. Similarly, the second extending region 20c₂ has a thickness T₁ less than a thickness T₂ of the second shielding region 20b₂, in which the thickness T₁ is far less than the thickness T₂, alternatively, the thickness T₁ is close to a minimum. The first extending region 20c₁ and the second extending region 20c₂ are employed to protect the underlying polysilicon layer without affecting the concentration of the heavily-doped regions 14c₁ and 14c₂. Thus, using the thicker shielding regions 20b₁ and 20b₂ as an ion-implantation mask, the LDD structure and the source/drain diffusion region can be achieved simultaneously with only one ion implantation process of adequate doping energy and dosage.

In the second TFT area II, the second gate insulating layer 22 further comprises a first extending region 22c₁ and a second extending region 22c₂. The first extending region 22c₁ extends laterally away from the first shielding region 22b₁ and covers the first heavily-doped region 16c₁. The second extending region 22c₂ extends laterally away from the second shielding region 22b₂ and covers the second heavily-doped region 16c₂. The first extending region 22c₁ has a thickness T₁ less than a thickness T₂ of the first shielding region 22b₁. Preferably, the thickness T₁ is far less than the thickness T₂. Alternatively, the thickness T₁ is close to a minimum. Similarly, the second extending region 22c₂ has a thickness T₁ less than a thickness T₂ of the second shielding region 22b₂, in which the thickness T₁ is far less than the thickness T₂, alternatively, the thickness T₁ is close to a minimum. The first extending region 22c₁ and the second extending region 22c₂ are employed to protect the underlying polysilicon layer without affecting the concentration of the heavily-doped regions 16c₁ and 16c₂. Thus, using the thicker shielding regions 22b₁ and 22b₂ as an ion-implantation mask, the LDD structure and the source/drain diffusion region can be achieved simultaneously with only one ion implantation process of adequate doping energy and dosage.

The fabrication method for the self-aligned LDD structures in the second embodiment is substantially similar to that of the first embodiment, with similar portions omitted herein. By modulating parameters of the photolithography and etching processes for the formation of the gate insulating layers 20 and 22, the etched thickness of the gate insulating layers 20 and 22 must be adequately modulated until the extending regions 20c₁, 20c₂, 22c, and 22c₂ outside the gate electrode layers 25 and 27 are retained and reach a preferred thickness T₁.

### THIRD EMBODIMENT

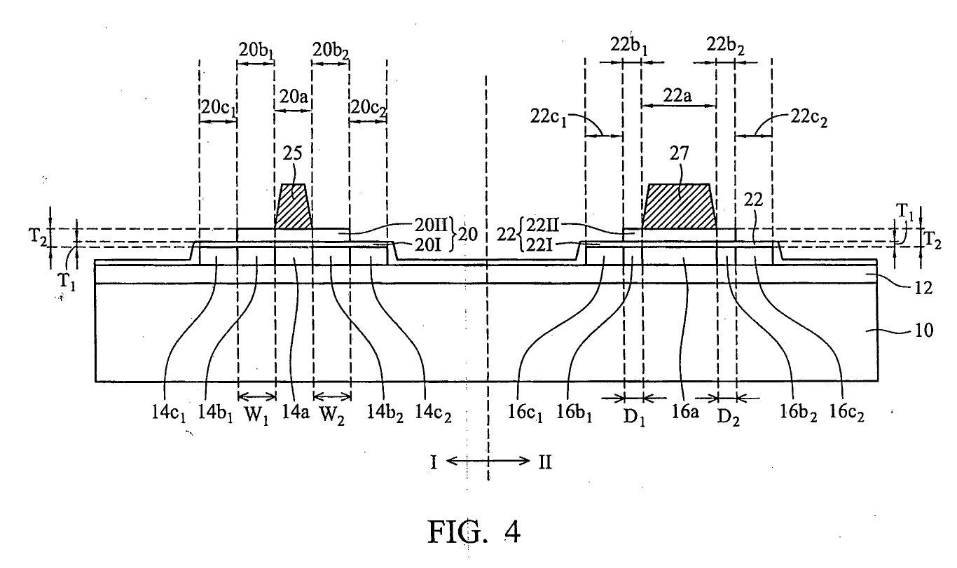

FIG. 4 is a cross-section of self-aligned LDD structures according to the third embodiment of the present invention. Elements in the third embodiment are substantially similar to that of the second embodiment, with the similar portions omitted below.

In the first TFT area I, the first gate insulating layer 20 is composed of a first insulating layer 20I and a second insulating layer 20II. Preferably, the first insulating layer 20I is a silicon oxide layer, a silicon nitride layer, a silicon-oxide-nitride layer or a combination thereof. Preferably, the second insulating layer 20II is a silicon oxide layer, a silicon nitride layer, a silicon-oxide-nitride layer, or a combination thereof. The first gate insulating layer 20 has a central region 20a, two shielding regions 20b₁ and 20b₂, and two extending regions 20c₁ and 20c₂. In the central region 20a, a double-layer structure composed of the first insulating layer 20I and the second insulating layer 20II covers the channel region 14a. In each of the shielding regions 20b, and 20b₂, a double-layer structure composed of the first insulating layer 20I and the second insulating layer 20II covers the LDD structure and is exposed laterally adjacent to the first gate electrode layer 25. In each of the extending regions 20c₁ and 20c₂, a single-layer structure composed of the first insulating layer 20I covers the source/drain diffusion region. Thus, a thickness T₁ of the extending regions 20c₁ and 20c₂ (the single-layer structure) is less than a thickness T₂ of the shielding regions 20b₁ and 20b₂ (the double-layer structure). Thus, using the thicker shielding regions 20b₁ and 20b₂ as an ion-implantation mask, the LDD structure and the source/drain diffusion region can be achieved simultaneously with only one ion implantation process of adequate doping energy and dosage.

In the second TFT area II, the second gate insulating layer 22 is composed of a first insulating layer 22I and a second insulating layer 22II. Preferably, the first insulating layer 22I is a silicon oxide layer, a silicon nitride layer, a silicon-oxide-nitride layer or a combination thereof. Preferably, the second insulating layer 22II is a silicon oxide layer, a silicon nitride layer, a silicon-oxide-nitride layer, or a combination thereof. The second gate insulating layer 22 has a central region 22a, two shielding regions 22b₁ and 22b₂, and two extending regions 22c₁ and 22c₂. In the central region 22a, a double-layer structure composed of the first insulating layer 22I and the second insulating layer 22II covers the channel region 16a. In each of the shielding regions 22b₁ and 22b₂, a double-layer structure composed of the first insulating layer 22I and the second insulating layer 22II covers the LDD structure and is exposed laterally adjacent to the second gate electrode layer 27. In each of the extending regions 22c₁ and 22c₂, a single-layer structure composed of the first insulating layer 22I covers the source/drain diffusion region. Thus, a thickness T₁ of the extending regions 22c₁ and 22c₂ (the single-layer structure) is less than a thickness T₂ of the shielding regions 22b₁ and 22b₂ (the double-layer structure). Thus, using the thicker shielding regions 22b₁ and 22b₂ as an ion-implantation mask, the LDD structure and the source/drain diffusion region can be achieved simultaneously with only one ion implantation process of adequate doping energy and dosage.

The fabrication method for the self-aligned LDD structures in the third embodiment is substantially similar to that of the first embodiment, with similar portions omitted herein. By modulating parameters of the photolithography and etching processes for the formation of the gate insulating layers 20 and 22, the etched thickness of the gate insulating layers 20 and 22 must be adequately modulated until the extending regions 20c₁, 20c₂, 22c₁ and 22c₂ outside the gate electrode layers 25 and 27 are retained and reach a preferred thickness T₁.

### FOURTH EMBODIMENT

The present invention provides a TFT device with a LDD structure having a single lightly-doped region laterally adjacent to a single sidewall of a gate electrode layer. Particularly, a gate insulating layer formed underneath the gate electrode layer has one shielding region exposed laterally adjacent to the single sidewall of the gate electrode layer. The shielding region is then used as a mask to perform one ion implantation process, thus obtaining a self-aligned LDD structure and a source/drain diffusion region simultaneously. The TFT device may be used in N-MOS TFT applications or P-MOS TFT applications. The TFT device may be used in a pixel array area, a peripheral driving-circuit area or a combination thereof.

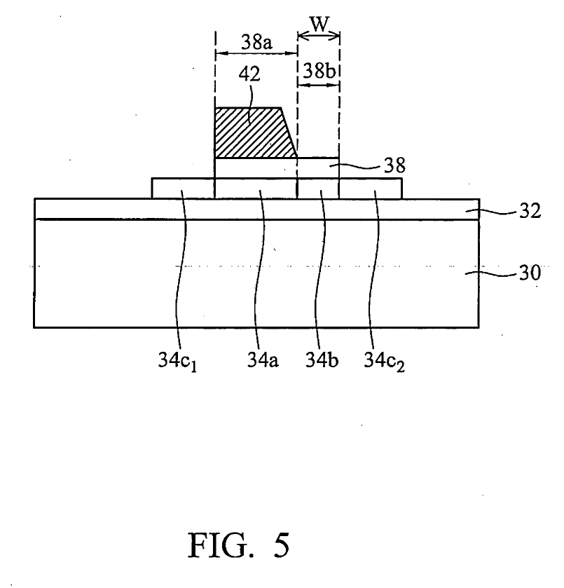

FIG. 5 is a cross-section of a self-aligned LDD structure according to the fourth embodiment of the present invention. A substrate 30 comprises a buffer layer 32, an active layer 34, a gate insulating layer 38 and a gate electrode layer 42 successively formed thereon. The substrate 30 is a transparent insulating substrate, such as a glass substrate. The buffer layer 32 is a dielectric layer, such as a silicon oxide layer. The active layer 34 is a semiconductor silicon layer, such as a polysilicon layer. The gate insulating layer 38 may be a silicon oxide layer, a silicon nitride layer, a SiON layer or a combination thereof. The gate electrode layer 42 may be a metallic layer or a polysilicon layer.

The active layer 34 comprises an undoped region 34a, a lightly-doped region 34b and two heavily-doped regions 34c, and 34c₂. The undoped region 34a serves as a channel region. The lightly-doped region 34b extends laterally away from the right side of the undoped region 34a and serves as an LDD structure. The first heavily-doped region 34c, extends laterally away from the left side of the undoped region 34a, and the second heavily-doped regions extends laterally away from the right side of the lightly-doped region 34b, resulting in a source/drain diffusion region. The lightly-doped region 34b has a doping concentration less than 2×10¹⁸ atom/cm³, and the heavily-doped region 34c₁ or 34c₂ has a doping concentration of 2×10¹⁹˜2×10²¹ atom/cm³.

The gate insulating layer 38 comprises a central region 38a and a shielding region 38b. The central region 38a covers the undoped region 34a, and is covered by the bottom of the gate electrode layer 42. The shielding region 38b extends laterally away from the right side of the central region 38a, and covers the lightly-doped region 34b, thus exposing the heavily-doped regions 34c₁ and 34c₂. Thus, using the shielding regions 38b as an ion-implantation mask, the LDD structure and the source/drain diffusion region can be achieved simultaneously with only one ion implantation process of adequate doping energy and dosage. The shielding region 38b has a lateral length W corresponding to a lateral length of the lightly-doped region 34b. Preferably, W=0.1 μm˜2.0 μm.

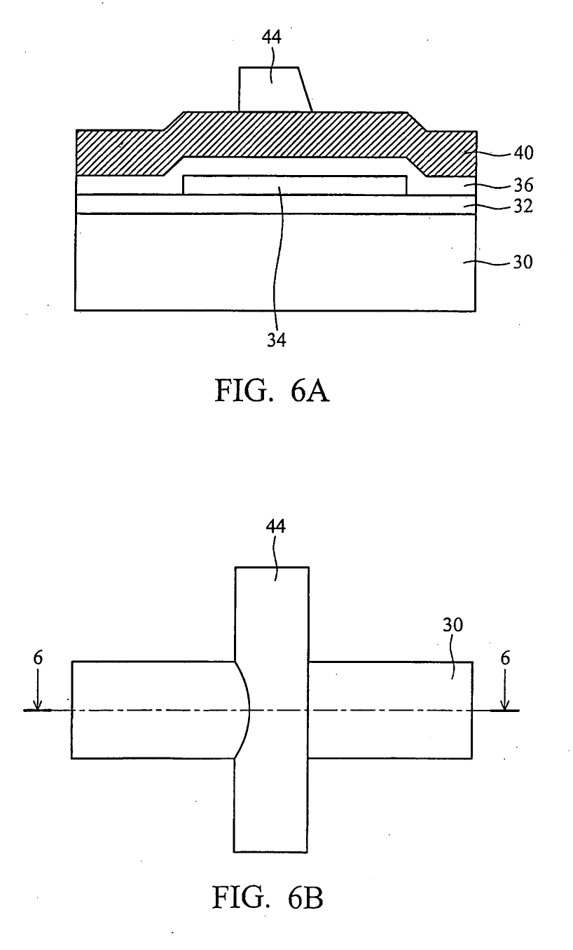

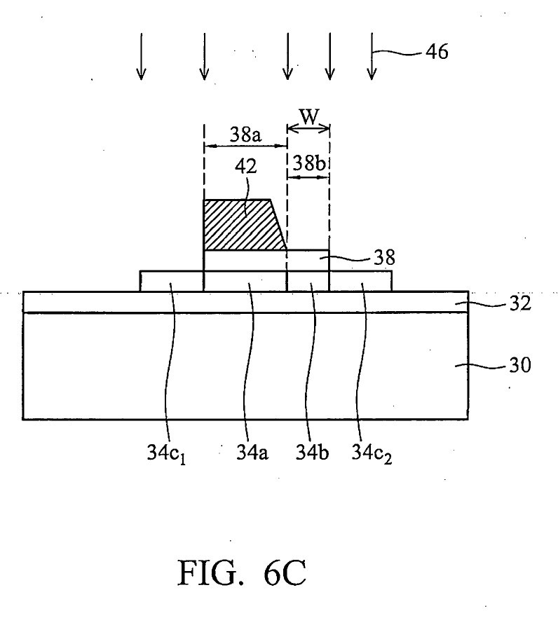

The fabrication method for the self-aligned LDD structure is described in FIGS. 6A-6C. FIG. 6B is a plane view of a photoresist layer and an active layer. FIG. 6A is a cross-section along line 6A-6A in FIG. 6B. FIG. 6C is a cross-section of the LDD structure.

In FIGS. 6A and 6B, a buffer layer 32 is deposited on the substrate 30, and then an active layer 34 is patterned on the buffer layer 32. Next, an insulating layer 36, a conductive layer 40 and a patterned photoresist layer 44 are successively deposited on the active layer 34 and the buffer layer 32. The insulating layer 36 may be a silicon oxide layer, a silicon nitride layer, a SiON layer or a combination thereof. The conductive layer 40 may be a metallic layer or a polysilicon layer. The patterned photoresist layer 44 corresponds to a predetermined gate pattern.

In FIG. 6C, the patterned photoresist layer 44 is used as a mask and an etching method is employed to pattern the conductive layer 40 as a gate electrode layer 42, and pattern the insulating layer 36 as a gate insulating layer 38. Then, the patterned photoresist layer 44 is removed. The gate insulating layer 38 comprises a central region 38a and a shielding region 38b. The central region 38a is covered by the bottom of the gate electrode layer 42. The shielding region 38b extends laterally away from the right side of the central region 38a, and covers a predetermined LDD pattern of the active layer 34, and exposes a predetermined source/drain pattern of the active layer 34. Preferably, the shielding region 38b has a lateral length W of 0.1˜2.0 μm. An effective etching method, such as plasma etching or reactive ion etching, may be employed to obtain the patterned structures as shown. The etching method also uses a reactive gas mixture of an oxygen-containing gas and a chlorine-containing gas, and adjusts the individual flow of the oxygen-containing gas or the chlorine-containing gas in a timely manner.

Finally, the gate electrode layer 42 and the shielding region 38b are used as a mask and an ion implantation process 46 is performed on the active layer 34 to form an undoped region 34a, a lightly-doped region 34b and two heavily-doped regions 34c₁ and 34c₂. The undoped region 34a is covered by the central region 38a to serve as a channel region. The lightly-doped region 34b extends laterally away from the right side of the undoped region 34a and is covered by the shielding region 38b to serve as an LDD structure. The lateral length of the lightly-doped region 34b also corresponds to the lateral length W of the shielding region 38b. The first heavily-doped region 34c₁ extends laterally away from the left side of the undoped region 34a, and the second heavily-doped regions 34c₂ extends laterally away from the right side of the lightly-doped region 34b, thus serving as a source/drain diffusion region.

The lateral length W of the shielding region 38b is 0.1˜2.0 μm, the doping energy is 10˜100 KeV, and a doping concentration of the lightly-doped region 34b is less than 2×10¹⁸ atom/cm³, and a doping concentration of the heavily-doped region 34c₁ and 34c₂ is 2×10¹⁹˜2×10²¹ atom/cm³. The thin film transistor is used in an N-MOS TFT, thus the LDD structure is an N⁻-doped region, and the source/drain diffusion region is an N⁺-doped region. Alternatively, the thin film transistor is used in a P-MOS TFT, thus the LDD structure is a P⁻-doped region, and the source/drain diffusion region is a P⁺-doped region. Subsequent interconnect processes including formation of inter-dielectric layers, contact vias and interconnects overlying the thin film transistor are omitted herein.

The self-aligned LDD structure and the fabrication method thereof have the following advantages.

First, by adjusting parameters of the etching process, the lateral length W of the shielding region 38b can be accurately controlled, thus ensuring proper positioning of the LDD structure and electric performance of the thin film transistor.

Second, since an extra photomask or a spacer structure for defining the LDD structure are omitted, shifting of the LDD structure due to photo misalignment in exposure technique is prevented, further improving accuracy in positioning the LDD structure.

Third, compared with the conventional method, the present invention can reduce one step of the ion implantation process, thus simplifying the procedure, decreasing process costs, increasing product yield and production rate. Additionally, the method is highly applicable to mass production.

Fourth, the single shielding region 38b can be the ion-implantation mask to form the LDD structure with single lightly-doped region. Thus, ensuring reliability and operating speed of two driving-voltage devices simultaneously.

### FIFTH EMBODIMENT

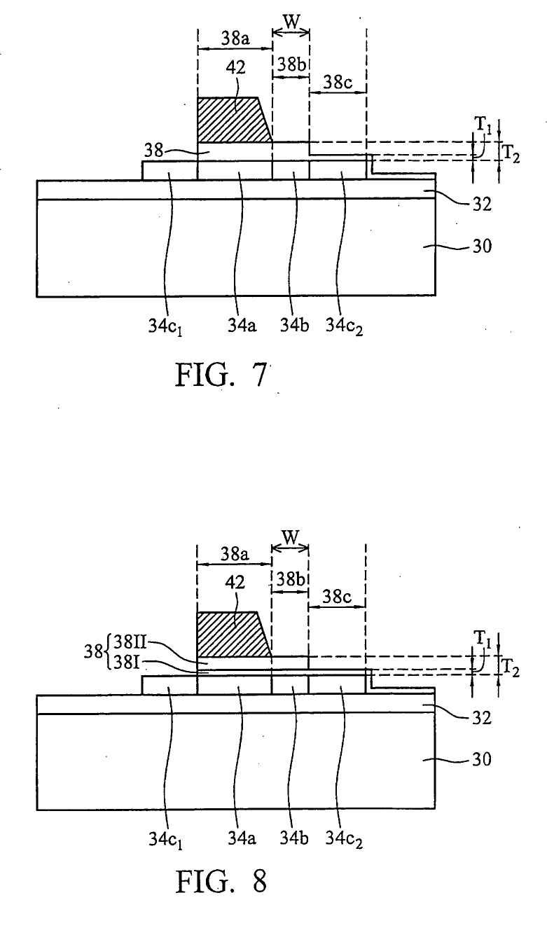

FIG. 7 is a cross-section of a self-aligned LDD structure according to the fifth embodiment of the present invention. The self-aligned LDD structure in the fifth embodiment is substantially similar to those of the fourth embodiment, with the similar portions omitted herein.

The gate insulating layer 38 further comprises an extending region 38c which extends laterally away from the right side of the shielding region 38b and covers the second heavily-doped region 34c₂. The extending region 38c has a thickness T₁ less than a thickness T₂ of the shielding region 38b. Preferably, the thickness T₁ is far less than the thickness T₂. Alternatively, the thickness T₁ is close to a minimum. Thus, using the thicker shielding region 38b as an ion-implantation mask, the LDD structure and the source/drain diffusion region can be achieved simultaneously with only one ion implantation process of adequate doping energy and dosage.

The fabrication method for the self-aligned LDD structure in the fifth embodiment is substantially similar to that of the fourth embodiment, with similar portions omitted herein. By modulating parameters of the photolithography and etching processes for the formation of the gate insulating layer 38, the etched thickness of the gate insulating layer 38 must be adequately modulated until the extending region 38c outside the gate electrode layer 42 is retained and reaches a preferred thickness T₁.

### SIXTH EMBODIMENT

FIG. 8 is a cross-section of a self-aligned LDD structure according to the sixth embodiment of the present invention. Elements in the sixth embodiment are substantially similar to that of the fifth embodiment, with the similar portions omitted below.

The gate insulating layer 38 is composed of a first insulating layer 38I and a second insulating layer 38II. Preferably, the first insulating layer 38I is a silicon oxide layer, a silicon nitride layer, a silicon-oxide-nitride layer or a combination thereof. Preferably, the second insulating layer 38II is a silicon oxide layer, a silicon nitride layer, a silicon-oxide-nitride layer, or a combination thereof. The gate insulating layer 38 has a central region 20a, a shielding region 38b and an extending region 38c. In the central region 38a, a double-layer structure composed of the first insulating layer 38I and the second insulating layer 38II covers the channel region 34a. In the shielding region 38b, a double-layer structure composed of the first insulating layer 38I and the second insulating layer 38II covers the LDD structure. In the extending region 38c, a single-layer structure composed of the first insulating layer 38I covers the source/drain diffusion region. Thus, a thickness T₁ of the extending region 38c (the single-layer structure) is less than a thickness T₂ of the shielding region 38b (the double-layer structure). Thus, using the thicker shielding region 38b as an ion-implantation mask, the LDD structure and the source/drain diffusion region can be achieved simultaneously with only one ion implantation process of adequate doping energy and dosage.

The fabrication method for the self-aligned LDD structure in the fifth embodiment is substantially similar to that of the fourth embodiment, with similar portions omitted herein. By modulating parameters of the photolithography and etching processes for the formation of the gate insulating layer 38, the etched thickness of the gate insulating layer 38 must be adequately modulated until the extending regions 38c outside the gate electrode layer 42 is retained and reaches a preferred thickness T₁.

### SEVENTH EMBODIMENT

The present invention provides a TFT device with a LDD structure having two lightly-doped regions with asymmetric lateral lengths. Particularly, a gate insulating layer formed underneath the gate electrode layer has two shielding regions, which are exposed laterally adjacent to the gate electrode layer and have different lateral lengths. The shielding regions are then used as a mask to perform one ion implantation process, thus obtaining a self-aligned LDD structure and a source/drain diffusion region simultaneously. The TFT device may be used in N-MOS TFT applications or P-MOS TFT applications. The TFT device may be used in a pixel array area, a peripheral driving-circuit area or a combination thereof.

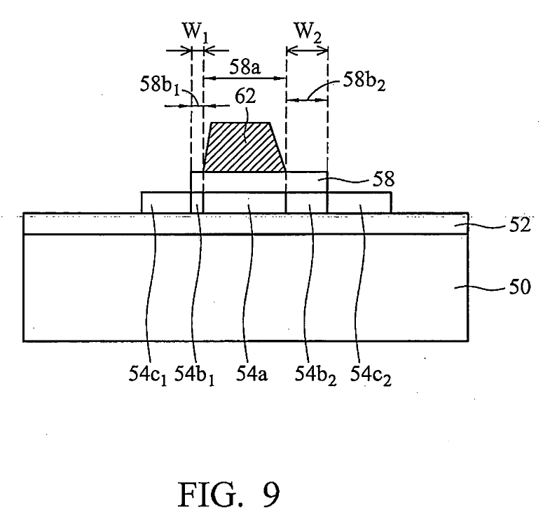

FIG. 9 is a cross-section of a self-aligned LDD structure according to the seventh embodiment of the present invention. A substrate 50 comprises a buffer layer 52, an active layer 54, a gate insulating layer 58 and a gate electrode layer 62 successively formed thereon. The substrate 50 is a transparent insulating substrate, such as a glass substrate. The buffer layer 52 is a dielectric layer, such as a silicon oxide layer. The active layer 54 is a semiconductor silicon layer, such as a polysilicon layer. The gate insulating layer 58 may be a silicon oxide layer, a silicon nitride layer, a SiON layer or a combination thereof. The gate electrode layer 62 may be a metallic layer or a polysilicon layer.

The active layer 54 comprises an undoped region 54a, two lightly-doped regions 54b₁ and 54b₂, and two heavily-doped regions 54c₁ and 54c₂. The undoped region 54a serves as a channel region. The two lightly-doped regions 54b₁ and 54b₂ extend laterally away from the undoped region 34a, respectively, to serve as an LDD structure. The two heavily-doped regions 54c₁ and 54c₂ extend laterally away from the two lightly-doped regions 54b₁ and 54b₂, respectively, to serve as a source/drain diffusion region. The lightly-doped region 54b₁ or 54b₂ has a doping concentration less than 2×10¹⁸ atom/cm³, and the heavily-doped region 54c₁ or 54c₂ has a doping concentration of 2×10¹⁹˜2×10²¹ atom/cm³.

The gate insulating layer 58 comprises a central region 58a and two shielding regions 58b₁ and 58b₂. The central region 58a covers the undoped region 54a, and is covered by the bottom of the gate electrode layer 62. The two shielding regions 58b₁ and 58b₂ extend laterally away from the central region 58a, respectively, and cover the two lightly-doped regions 54b₁ and 54b₂, without covering the two heavily-doped regions 54c₁ and 54c₂. Thus, using the shielding regions 58b₁ and 58b₂ as an ion-implantation mask, the LDD structure and the source/drain diffusion region can be achieved simultaneously with only one ion implantation process of adequate doping energy and dosage. The first shielding region 58b₁ has a lateral length W₁ corresponding to a lateral length of the first lightly-doped region 54b₁, and the second shielding region 58b₂ has a lateral length W₂ corresponding to a lateral length of the second lightly-doped region 54b₂. Preferably, W₁=0.1˜2.0 μm, and W₂=0.1˜2.0 μm. Depending on requirements for circuit designs, the size and asymmetry of the lateral lengths W₁ and W₂ may be adequately modified. For example, W₁≠W₂, alternatively, W₁<W₂.

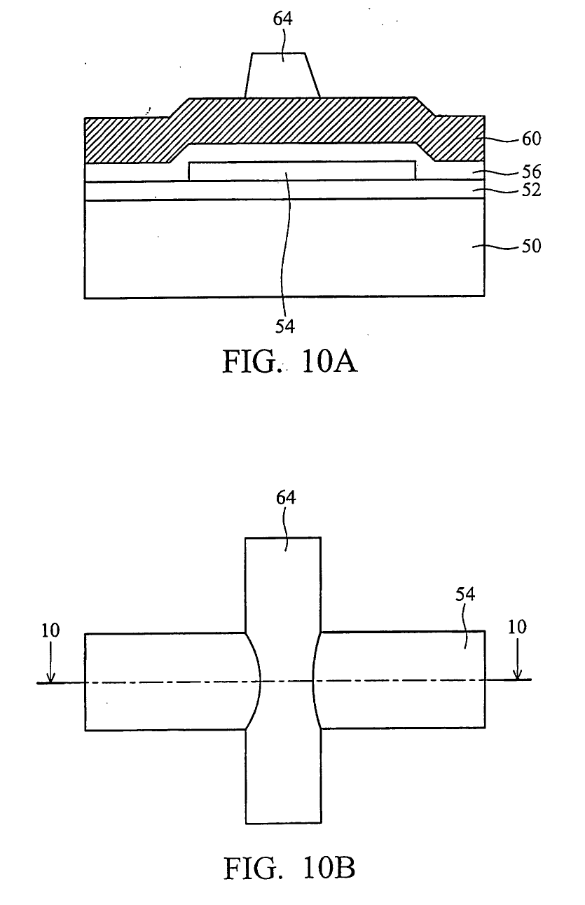

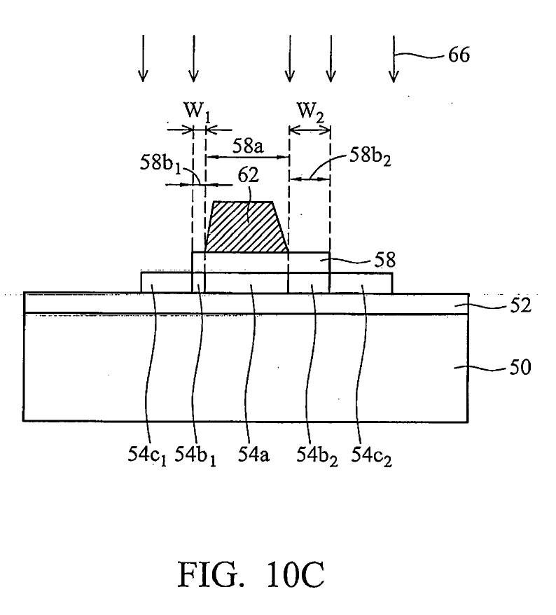

The fabrication method for the self-aligned LDD structure is described in FIGS. 10A˜10C. FIG. 10B is a plane view of a photoresist layer and an active layer. FIG. 10A is a cross-section along line 10A-10A in FIG. 10B. FIG. 10C is a cross-section of the LDD structure.

In FIGS. 10A and 10B, a buffer layer 52 is deposited on the substrate 50, and then an active layer 54 is patterned on the buffer layer 52. Next, an insulating layer 56, a conductive layer 60 and a patterned photoresist layer 64 are successively deposited on the active layer 54 and the buffer layer 52. The insulating layer 56 may be a silicon oxide layer, a silicon nitride layer, a SiON layer or a combination thereof. The conductive layer 60 may be a metallic layer or a polysilicon layer. The patterned photoresist layer 64 corresponds to a predetermined gate pattern.

In FIG. 10C, the patterned photoresist layer 64 is used as a mask and an etching method is employed to pattern the conductive layer 60 as a gate electrode layer 62, and pattern the insulating layer 56 as a gate insulating layer 58. Then, the patterned photoresist layer 64 is removed. The gate insulating layer 58 comprises a central region 58a and two shielding regions 58b, and 58b₂. The central region 58a is covered by the bottom of the gate electrode layer 62. The two shielding regions 58b, and 58b₂ extend laterally away from the central region 58a, respectively, and cover a predetermined LDD pattern of the active layer 54, and expose a predetermined source/drain pattern of the active layer 54. Preferably, the first shielding region 58b₁ has a lateral length W₁ of 0.1˜2.0 μm, and the second shielding region 58b₂ has a lateral length W₂ of 0.1˜2.0 μm. Preferably, W₁≠W₂. An effective etching method, such as plasma etching or reactive ion etching, may be employed to obtain the patterned structures as shown. Also, the etching method uses a reactive gas mixture of an oxygen-containing gas and a chlorine-containing gas, and adjusts the individual flow of the oxygen-containing gas or the chlorine-containing gas in a timely manner.

Finally, the gate electrode layer 62 and the shielding regions 58b₁ and 58b₂ are used as a mask and an ion implantation process 66 is performed on the active layer 54 to form an undoped region 54a, two lightly-doped regions 54b₁ and 54b₂, and two heavily-doped regions 54c₁ and 54c₂. The undoped region 54a is covered by the central region 58a to serve as a channel region. The lightly-doped regions 54b₁ and 54b₂ extend laterally away from the undoped region 54a, respectively, and are covered by the shielding regions 58b₁ and 58b₂ to serve as an LDD structure. The lateral length of the first lightly-doped region 54b₁ also corresponds to the lateral length W₁ of the first shielding region 58b₁, and the lateral length of the second lightly-doped region 54b₂ corresponds to the lateral length W₂ of the second shielding region 58b₂. The first heavily-doped region 54c₁ extends laterally away from the first lightly-doped region 54b₁, and the second heavily-doped region 54c₂ extends laterally away from the second lightly-doped region 54b₂, thus serving as a source/drain diffusion region.

The doping energy is 10˜100 KeV, and a doping concentration of the lightly-doped region 54b₁ or 54b₂ is less than 2×10¹⁸ atom/cm³, and a doping concentration of the heavily-doped region 54c₁ or 54c₂ is 2×10¹⁹˜2×10²¹ atom/cm³. The thin film transistor is used in an N-MOS TFT, thus the LDD structure is an N⁻-doped region, and the source/drain diffusion region is an N⁺-doped region. Alternatively, the thin film transistor is used in a P-MOS TFT, thus the LDD structure is a P⁻-doped region, and the source/drain diffusion region is a P⁺-doped region. Subsequent interconnect process including formation of inter-dielectric layers, contact vias and interconnects overlying the thin film transistor is omitted herein.

The self-aligned LDD structure and the fabrication method thereof have the same advantages described in the fourth embodiment. Moreover, the two shielding regions 58b₁ and 58b₂ having different lateral lengths can be the ion-implantation mask to form the LDD structure with two lightly-doped regions 54b₁ and 54b₂ with different lateral lengths. Thus, the asymmetric structure ensures reliability and operating speed of a specific driving-voltage device.

### EIGHTH EMBODIMENT

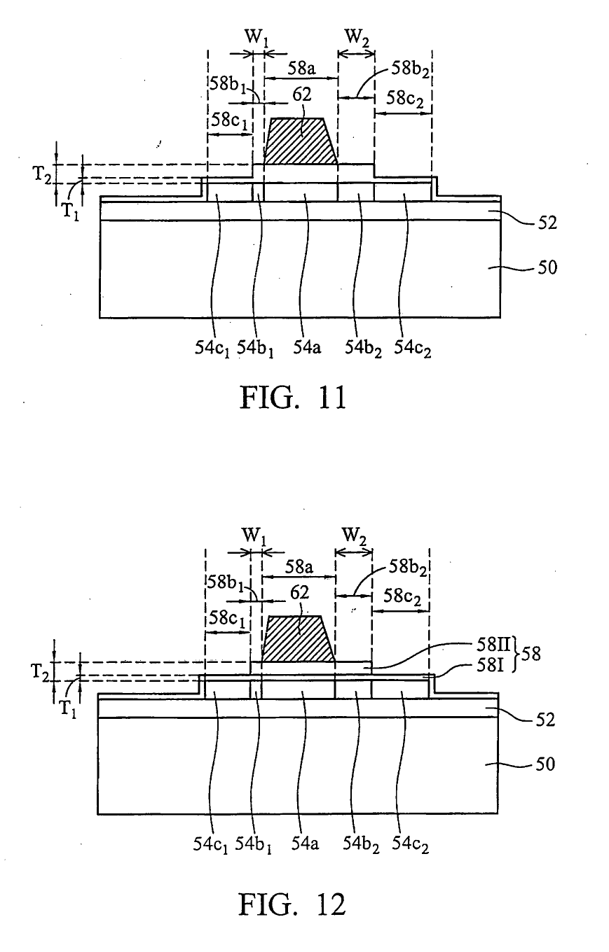

FIG. 11 is a cross-section of a self-aligned LDD structure according to the eighth embodiment of the present invention. The self-aligned LDD structure in the eighth embodiment is substantially similar to those of the seventh embodiment, with the similar portions omitted herein.

The gate insulating layer 58 further comprises a first extending region 58c₁ and a second extending region 58c₂. The first extending region 58c₁ extends laterally away from the first shielding region 58b₁ and covers the first heavily-doped region 54c₁. The second extending region 58c₂ extends laterally away from the second shielding region 58b₂ and covers the second heavily-doped region 54c₂. The first extending region 58c₁ has a thickness T₁ less than a thickness T₂ of the first shielding region 58b₁. Preferably, the thickness T₁ is far less than the thickness T₂. Alternatively, the thickness T₁ is close to a minimum. Similarly, the second extending region 58c₂ has a thickness T₁ less than a thickness T₂ of the second shielding region 58b₂, in which the thickness T₁ is far less than the thickness T₂, alternatively, the thickness T₁ is close to a minimum. Thus, using the thicker shielding regions 58b₁ and 58b₂ as an ion-implantation mask, the LDD structure and the source/drain diffusion region can be achieved simultaneously with only one ion implantation process of adequate doping energy and dosage.

The fabrication method for the self-aligned LDD structures in the eighth embodiment is substantially similar to that of the seventh embodiment, with similar portions omitted herein. By modulating parameters of the photolithography and etching processes for the formation of the gate insulating layer 58, the etched thickness of the gate insulating layer 58 must be adequately modulated until the extending regions 58c₁, 58c₂ outside the gate electrode layers 62 are retained and reaches a preferred thickness T₁.

### NINTH EMBODIMENT

FIG. 12 is a cross-section of a self-aligned LDD structure according to the ninth embodiment of the present invention. Elements in the ninth embodiment are substantially similar to that of the eighth embodiment, with the similar portions omitted below.

The gate insulating layer 58 is composed of a first insulating layer 58I and a second insulating layer 58II. Preferably, the first insulating layer 58I is a silicon oxide layer, a silicon nitride layer, a silicon-oxide-nitride layer or a combination thereof. Preferably, the second insulating layer 58II is a silicon oxide layer, a silicon nitride layer, a silicon-oxide-nitride layer, or a combination thereof. The gate insulating layer 58 has a central region 58a, two shielding regions 58b, and 58b₂, and two extending regions 58c₁ and 58c₂. In the central region 58a, a double-layer structure composed of the first insulating layer 58I and the second insulating layer 58II covers the channel region 54a. In each of the shielding regions 58b₁ and 58b₂, a double-layer structure composed of the first insulating layer 58I and the second insulating layer 58II covers the LDD structure and is exposed laterally adjacent to the gate electrode layer 25. In each of the extending regions 58c₁ and 58c₂, a single-layer structure composed of the first insulating layer 58I covers the source/drain diffusion region. Thus, a thickness T₁ of the extending regions 58c₁ and 58c₂ (the single-layer structure) is less than a thickness T₂ of the shielding regions 58b₁ and 58b₂ (the double-layer structure). Thus, using the thicker shielding regions 58b₁ and 58b₂ as an ion-implantation mask, the LDD structure and the source/drain diffusion region can be achieved simultaneously with only one ion implantation process of adequate doping energy and dosage.

The fabrication method for the self-aligned LDD structure in the ninth embodiment is substantially similar to that of the seventh embodiment, with similar portions omitted herein. By modulating parameters of the photolithography and etching processes for the formation of the gate insulating layer 58, the etched thickness of the gate insulating layer 58 must be adequately modulated until the extending regions 58c₁ and 58c₂ outside the gate electrode layer 62 are retained and reaches a preferred thickness T₁.

### TENTH EMBODIMENT

The present invention provides an attenuated phase shifting mask cooperating with a photolithography process for the shielding regions and extending regions of a gate insulating layer. Then, the shielding regions are used as a mask to perform one ion implantation process, thus obtaining a self-aligned LDD structure and a source/drain diffusion region simultaneously. Preferably, the fabrication method is used for a TFT device with a LDD structure having two lightly-doped regions with asymmetric lateral lengths. The TFT device may be used in N-MOS TFT applications or P-MOS TFT applications. The TFT device may be used in a pixel array area, a peripheral driving-circuit area or a combination thereof.

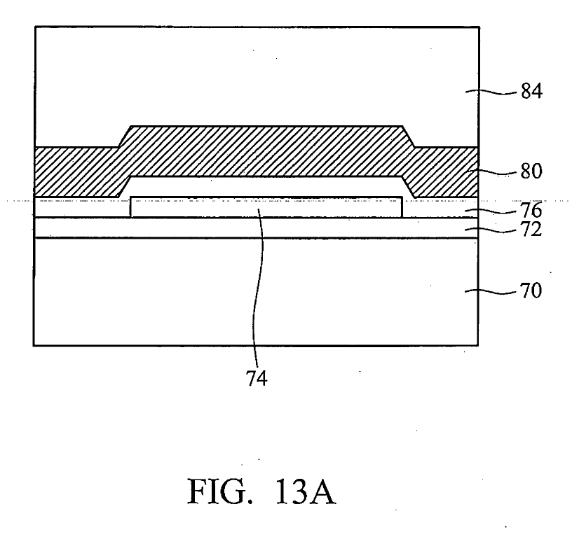

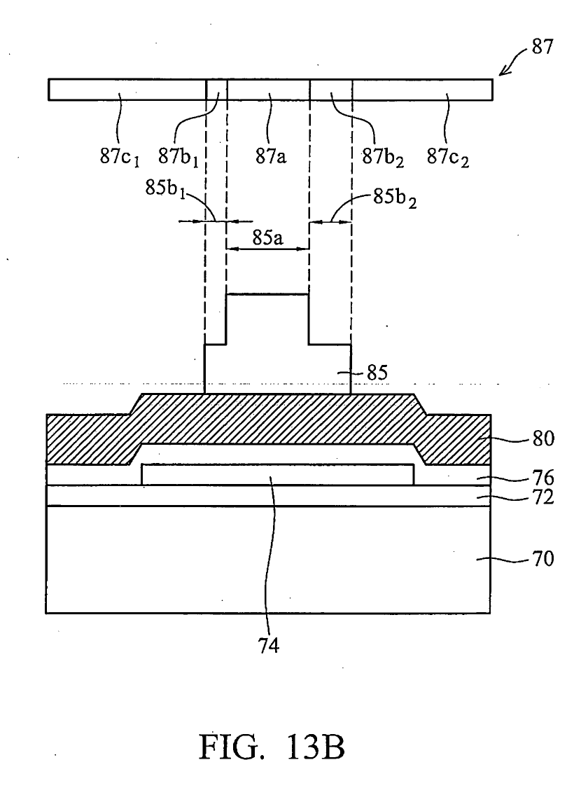

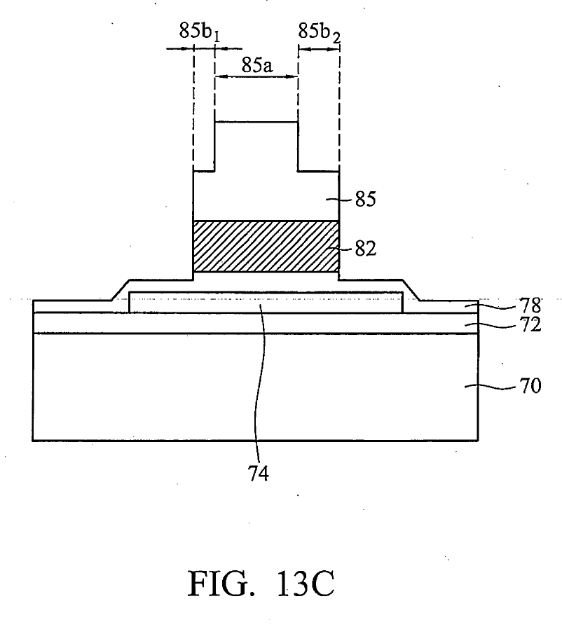

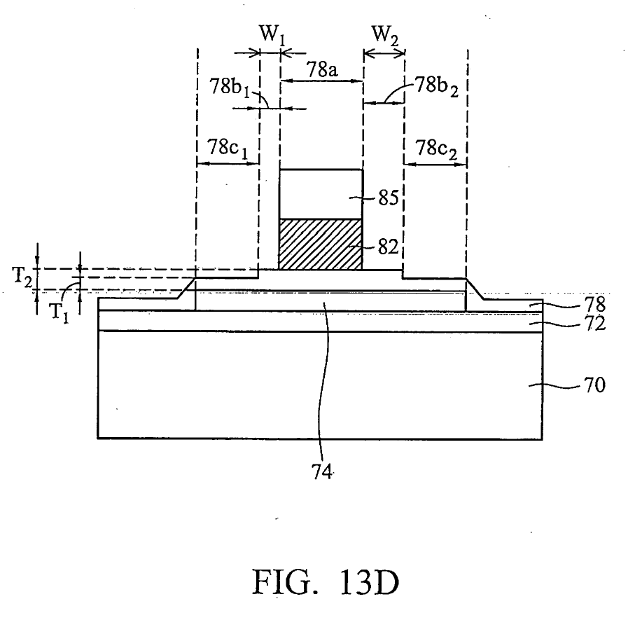

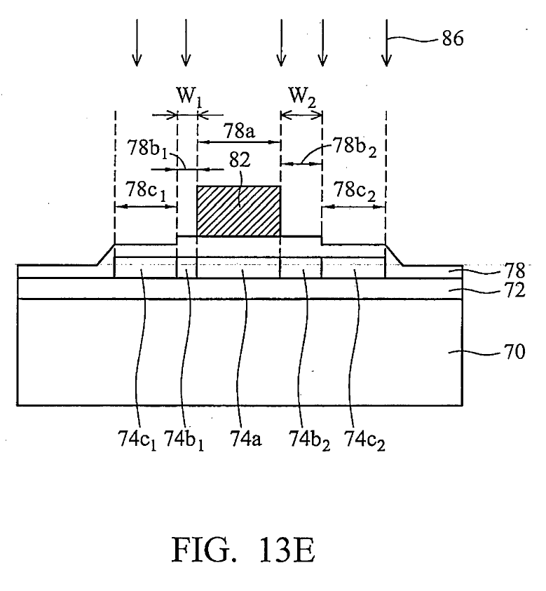

FIGS. 13A to 13E are cross-sections of a photolithography process with an attenuated phase shifting mask for a self-aligned LDD structure according to the tenth embodiment of the present invention.

In FIG. 13A, a substrate 70 comprises a buffer layer 72, on which an active layer 74, an insulating layer 76, a conductive layer 80 and a photoresist layer 84 are successively formed. The substrate 70 is a transparent insulating substrate or a glass substrate. The buffer layer 72 is a dielectric layer or a silicon oxide layer. The insulating layer 76 may be a silicon oxide layer, a silicon nitride layer, a SiON layer or a combination thereof. The conductive layer 80 may be a metallic layer or a polysilicon layer.

In FIG. 13B, an attenuated phase shifting mask 87 is used and exposure and development processes are performed to pattern the photoresist layer 84 as a protrusion-shaped photoresist layer 85. For example, the attenuated phase shifting mask 87 comprises an opaque area 87a of approximately 0% transparency, two phase-shifting areas 87b₁ and 87b₂ extending laterally away from the opaque area 87a respectively, and two transparent areas 87c₁ and 87c₂ extending laterally away from the two phase-shifting areas 87b₁ and 87b₂ respectively. The opaque area 87a corresponds to a predetermined gate pattern, the two phase-shifting areas 87b₁ and 87b₂ correspond to a predetermined LDD structure of the active layer 74, and the two transparent areas 87c₁ and 87c₂ correspond to a predetermined source/drain diffusion region of the active layer 74. Generally, the transparency of the phase-shifting area 87b₁ or 87b₂ is different from the transparency of the transparent area 87c₁ or 87c₂, and the transparency difference can be adequately modified in accordance with requirements for product and process designs. When the attenuated phase shifting mask 87 is utilized to perform the photolithography, process on a positive-type photoresist, the areas 87a, 87b₁, 87b₂ 87c₁ and 87c₂ having different transparencies make corresponding areas on the photoresist respectively receive different light intensity to achieve an incomplete exposure result. Therefore, each developed depth of the corresponding areas on the photoresist layer 84 is different, resulting in the protrusion-shaped photoresist layer 85. Preferably, the protrusion-shaped photoresist layer 85 has a first region 85a thicker than each of two second regions 85b₁ and 85b₂. In addition, by rearranging the areas 87a, 87b₁, 87b₂ 87c₁ and 87c₂, the attenuated phase shifting mask 87 can be utilized to perform the photolithography process on a negative-type photoresist to achieve the protrusion-shaped photoresist layer 85.

Next, in FIG. 13C, the protrusion-shaped photoresist layer 85 is used as a mask and an etching method is employed to remove the exposed regions of the conductive layer 80 and the insulating layer 76, a part of the insulating layer 76 is retained to cover the active layer 74 and the buffer layer 72. Then, in FIG. 13D, the protrusion-shaped photoresist layer 85 is continuously thinned until the two second regions 85b₁ and 85b₂ and the conductive layer 80 underlying the second regions 85b₁ and 85b₂ are completely removed. Thus, the conductive layer 80 is patterned as a gate electrode layer 82, and the insulating layer 76 is patterned as a gate insulating layer 78. The photoresist layer 85 is then removed. An effective etching method, such as plasma etching or reactive ion etching, may be employed to obtain the patterned structures as shown. The etching method also uses a reactive gas mixture of an oxygen-containing gas and a chlorine-containing gas, and adjusts the individual flow of the oxygen-containing gas or the chlorine-containing gas in a timely manner.

The gate insulating layer 78 comprises a central region 78a, two shielding regions 78b₁ and 78b₂ and two extending regions 78c₁ and 78c₂. The central region 78a is covered by the bottom of the gate electrode layer 82. The two shielding regions 78b₁ and 78b₂ extend laterally away from the central region 78a, respectively, and cover a predetermined LDD structure of the active layer 74. The two extending regions 78c₁ and 78c₂ extend laterally away from the two shielding regions 78b₁ and 78b₂, respectively, and cover a predetermined source/drain diffusion region of the active layer 74. The first shielding region 78b₁ has a lateral length W₁, and the second shielding region 78b₂ has a lateral length W₂. Preferably, W₁=0.1˜2.0 μm, and W₂=0.1˜2.0 μm. Depending on requirements for circuit designs, the size and asymmetry of the lateral lengths W₁ and W₂ may be adequately modified. For example, W₁≠W₂, alternatively, W₁<W₂. The first extending region 78c₁ has a thickness T, less than a thickness T₂ of the first shielding region 78b₁. Preferably, the thickness T₁ is far less than the thickness T₂. Alternatively, the thickness T₁ is close to a minimum. Similarly, the second extending region 78c₂ has a thickness T₁ less than a thickness T₂ of the second shielding region 78b₂, in which the thickness T₁ is far less than the thickness T₂, alternatively, the thickness T₁ is close to a minimum.

Finally, in FIG. 13E, the gate electrode layer 82 and the shielding regions 78b₁ and 78b₂ are used as a mask and an ion implantation process 86 is performed on the active layer 74 to form an undoped region 74a, two lightly-doped regions 74b₁ and 74b₂, and two heavily-doped regions 74c₁ and 74c₂. The undoped region 74a is covered by the central region 78a to serve as a channel region. The lightly-doped regions 74b₁ and 74b₂ extend laterally away from the undoped region 74a, respectively, and are covered by the shielding regions 78b₁ and 78b₂ to serve as an LDD structure. The lateral length of the first lightly-doped region 74b₁ also corresponds to the lateral length W₁ of the first shielding region 78b₁, and the lateral length of the second lightly-doped region 74b₂ corresponds to the lateral length W₂ of the second shielding region 78b₂. The two heavily-doped regions 74c₁ and 74c₂ extend laterally away from the two lightly-doped regions 74b₁ and 74b₂ to serve as a source/drain diffusion region.

The doping energy is 10˜100 KeV, and a doping concentration of the lightly-doped region 74b₁ or 74b₂ is less than 2×10¹⁸ atom/cm³, and a doping concentration of the heavily-doped region 74c₁ or 74c₂ is 2×10¹⁹˜2×10²¹ atom/cm³. The thin film transistor is used in an N-MOS TFT, thus the LDD structure is an N⁻-doped region, and the source/drain diffusion region is an N⁺-doped region. Alternatively, the thin film transistor is used in a P-MOS TFT, thus the LDD structure is a P⁻-doped region, and the source/drain diffusion region is a P⁺-doped region.

Subsequent interconnect process including formation of inter-dielectric layers, contact vias and interconnects overlying the thin film transistor is omitted herein. Also, the fabrication method described in the tenth embodiment can be utilized for the TFT devices shown in FIGS. 9 and 12.

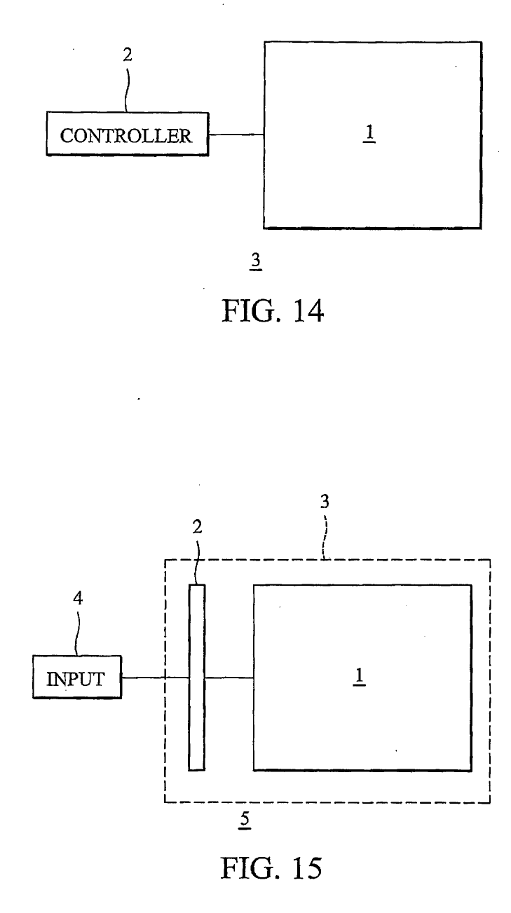

FIG. 14 is a schematic diagram of a display device 3 comprising the self-aligned LDD TFT structures in accordance with embodiments of the present invention. The display panel 1 can be couple to a controller 2, forming a display device 3 as shown in FIG. 14. The controller 3 can comprise a source and a gate driving circuits (not shown) to control the display panel 1 to render image in accordance with an input.

FIG. 15 is a schematic diagram of an electronic device 5, incorporating a display comprising the self-aligned LDD TFT structures in accordance with one embodiment of the present invention. An input device 4 is coupled to the controller 2 of the display device 3 shown in FIG. 4 can include a processor or the like to input data to the controller 2 to render an image. The electronic device 5 may be a portable device such as a PDA, notebook computer, tablet computer, cellular phone, or a desktop computer.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

1. A method of forming a semiconductor device, comprising the steps of:
forming a first and a second semiconductor structures, each comprising the steps of:
providing a semiconductor layer having a first region and a second region;
providing a first masking layer over the first region of the semiconductor layer, said first masking layer comprising a material that provides a permeable barrier to dopant; and
exposing the semiconductor layer, including the first region covered by the first masking layer, to a first dopant, wherein the first region covered by the first masking layer is lightly doped with the first dopant in comparison to the second region not covered by the first masking layer;
wherein the first region of the first semiconductor structure is of a different lateral length from the first region of the second semiconductor structure.

2. The method as claimed in claim 1, wherein the first semiconductor structure is a pixel array structure, and the second semiconductor structure is a peripheral driving-circuit structure.

3. The method as in claim 1, wherein the method further comprising for each semiconductor structure, the step of providing a second masking layer over the second region of the semiconductor layer, said second masking layer comprising a material that provides a permeable barrier to dopant, wherein the second masking layer is thinner than the first masking layer.

4. The method of claim 3, wherein the first and second semiconductor structures are adjacent, and wherein the second masking layer of each semiconductor structure extends to be joined in a common region.

5. The method as claimed in claim 1, wherein each first region of the first and second semiconductor structures comprises a first and a second sections, wherein the first section is of a different lateral length from the second section.

6. The method as claimed in claim 1, wherein the first region of the semiconductor layer has a doping concentration less than 2×10¹⁸ atom/cm³, and the second region of the semiconductor layer has a doping concentration of 2×10¹⁹˜1×10²¹ atom/cm³.

7. A method of forming a semiconductor device, comprising the steps of:
providing a semiconductor layer having a first region and a second region;
providing a first masking layer over the first region of the semiconductor layer, said first masking layer comprising a material that provides a permeable barrier to dopant; and
exposing the semiconductor layer, including the first region covered by the first masking layer, to a first dopant, wherein the first region covered by the first masking layer is lightly doped with the first dopant in comparison to the second region not covered by the first masking layer;
providing a second masking layer over the second region of the semiconductor layer, said second masking layer comprising a material that provides a permeable barrier to dopant, wherein the second masking layer is thinner than the first masking layer.

8. The method as claimed in claim 7, wherein each first region of the first and second semiconductor structures comprises first and second sections, wherein the first section is of a different lateral length from the second section.

9. The method as claimed in claim 7, wherein the first region of the semiconductor layer has a doping concentration less than 2×10¹⁸ atom/cm³, and the second region of the semiconductor layer has a doping concentration of 2×10¹⁹˜1×10²¹ atom/cm³.

10. A method of forming a semiconductor device, comprising the steps of:
providing a semiconductor layer having a first region and a second region;
providing a first masking layer over the first region of the semiconductor layer, said first masking layer comprising a material that provides a permeable barrier to dopant; and
exposing the semiconductor layer, including the first region covered by the first masking layer, to a first dopant, wherein the first region covered by the first masking layer is lightly doped with the first dopant in comparison to the second region not covered by the first masking layer;
wherein the first region comprises first and second sections, wherein the first section is of a different lateral length from the second section.

11. The method as in claim 10, wherein the method further comprising the step of providing a second masking layer over the second region of the semiconductor layer, said second masking layer comprising a material that provides a permeable barrier to dopant, wherein the second masking layer is thinner than the first masking layer.

12. The method as claimed in claim 10, wherein the first region of the semiconductor layer has a doping concentration less than 2×10¹⁸ atom/cm³, and the second region of the semiconductor layer has a doping concentration of 2×10¹⁹˜1×10²¹ atom/cm³.

13. A display device, comprising:
a display panel comprising a self-aligned LDD TFT, comprising:
a substrate having a first and a second semiconductor structures;
each semiconductor structure comprising a semiconductor layer having a channel region formed on the substrate, a first doping region formed on both sides of the channel region, and a second doping region formed on both sides of the first doping region; and
a controller coupled to the display panel to control the display panel to render an image in accordance an input;
wherein the first doping region of the first semiconductor structure is of a different lateral length from the first doping region of the second semiconductor structure.

14. The display device as claimed in claim 13, wherein the first region comprises a first and a second sections, wherein the first section is of a different lateral length from the second section.

15. An electronic device, comprising:
a display panel as claim in claim 13; and
a controller coupled to the display panel to control the display panel to render an image in accordance an input; and
an input device couple to the controller of the display device to render an image.
